(19) United States
(12) Patent Application Publication
(10) Pub. No.: US 2022/0134480 A1
(43) Pub. Date: May 5, 2022

(54) LASER ROUGHENING: ENGINEERING THE ROUGHNESS OF THE BURL TOP

(71) Applicant: ASML Holding N.V., Veldhoven (NL)

(72) Inventors: Damoon SOHRABIBABAHEIDARY, Norwalk, CT (US); Christopher John MASON, Newtown, CT (US); Peter HELMUS, New Milford, CT (US); Mehmet Ali AKBAS, Cheshire, CT (US); Bensely ALBERT, Trumbull, CT (US); Benjamin David DAWSON, Trumbull, CT (US)

(73) Assignee: ASML Holding N.V., Veldhoven (NL)

(21) Appl. No.: 17/431,538

(22) PCT Filed: Feb. 3, 2020
(86) PCT No.: PCT/EP2020/052551

§ 371 Date: Aug. 17, 2021

Related U.S. Application Data
(60) Provisional application No. 62/807,361, filed on Feb. 19, 2019.

(51) Int. Cl. B23K 26/352; G03F 7/20; B23K 26/06

(52) U.S. Cl. CPC B23K 26/3584; B23K 26/0665; B23K 26/0626; G03F 7/707

(57) ABSTRACT

Methods, computer program products, and apparatuses for reducing sticking during a lithography process are disclosed. An exemplary method of reducing sticking of an object to a modified surface that is used to support the object in a lithography process can include controlling a light source to deliver light to a native surface thereby causing ablation of at least a portion of the native surface to increase the roughness of the native surface thereby forming the modified surface. The increased roughness reduces the ability of the object to stick to the modified surface.

### CROSS-REFERENCE TO RELATED APPLICATIONS

This application claims priority of U.S. Provisional Patent Application No. 62/807,361, which was filed on Feb. 19, 2019, and which is incorporated herein in its entirety by reference.

### BACKGROUND

A lithographic projection apparatus can be used, for example, in the manufacture of integrated circuits (ICs). In such a case, a patterning device (e.g., a mask) may contain or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatuses, the pattern on the entire patterning device is transferred onto one target portion in one go; such an apparatus may also be referred to as a stepper. In an alternative apparatus, a step-and-scan apparatus can cause a projection beam to scan over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices can be found in, for example, U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

As noted, lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the amount of functional elements, such as transistors, per device has been steadily increasing over decades, following a trend referred to as “Moore's law.” At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is can be referred to as low-k1 lithography, according to the resolution formula CD=k1×λ/NA, where λ is the wavelength of radiation employed (e.g., 248 nm or 193 nm), NA is the numerical aperture of projection optics in the lithographic projection apparatus, CD is the “critical dimension”—generally the smallest feature size printed—and k1 is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET). The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

### SUMMARY

Disclosed is a method for reducing sticking of an object to a modified surface that is used to support the object in a lithography process. The method includes controlling a light source to deliver light to a native surface thereby causing ablation of at least a portion of the native surface to increase the roughness of the native surface thereby forming the modified surface. The increased roughness reduces the ability of the object to stick to the modified surface.

In some variations, the light source can be a laser and the native surface can include a top surface of a burl. Controlling of the light source can include setting an energy density of the light source to generate light having a fluence at the native surface that, when delivered to the surface, causes selective ablation of the native surface based on an atomic structure of the native surface, the selective ablation reducing a surface area for contacting the object. The native surface can have crystalline grains separated by grain boundaries, where the selective ablation removes material of the grain boundaries and causes essentially no ablation of the crystalline grains. Also, the controlling can include adjusting one or more of an intensity and/or focus of the light source to set the energy density based on a desired roughness of the modified surface.

In other variations, the controlling can include delivering light at separated locations on the native surface causing ablation of a portion of the grain boundaries, the delivering causing the modified surface to comprise roughened areas having a separation between them. The separation can be greater than a spot size of the light source. Also, a separation between locations of the delivery of light can be less than a spot size of the light source. The delivering of the light can also be across hilltops on a top surface of a burl forming part of a reticle clamp.

In an interrelated aspect, a non-transitory machine-readable medium stores instructions which, when executed by at least one programmable processor, causes the programmable processor to perform operations including controlling a light source to deliver light to a native surface thereby causing ablation of at least a portion of the native surface to increase the roughness of the native surface thereby forming a modified surface, where the increased roughness reduces the ability of an object to stick to the modified surface.

In some variations, the controlling can include setting an energy density of the light source to generate light having a fluence at the native surface that, when delivered to the surface, causes selective ablation of the native surface based on an atomic structure of the native surface, the selective ablation reducing a surface area for contacting the object.

Also, in other variations, the controlling can include adjusting one or more of an intensity and/or focus of the light source to set the energy density based on a desired roughness of the modified surface. The controlling can further include delivering light at separated locations on the native surface causing ablation of a portion of the grain boundaries, the delivering causing the modified surface to comprise roughened areas having a separation between them.

In yet another interrelated aspect, an apparatus can have a modified surface configured to contact an object, the modified surface being formed from a material comprising a grain structure including crystalline grains and grain boundaries, where the modified surface has a roughness based at least on crystalline grain peaks and crystalline grain boundary valleys located below the crystalline grain peaks.

In some variations, the roughness can be the root-mean-square of height of the modified surface. The roughness can be between 3 and 35 nm, between 20 and 35 nm, or greater than 2 nm. Also, the roughness of the native surface can be less than 3 nm. The apparatus can have, in at least one location on the modified surface, between 2 nm and 30 nm of grain boundary material removed from the native surface.

In other variations, the apparatus can include burls extending from a substrate, where the modified surface is on top surfaces of the burls. The substrate can be a reticle clamp, wafer clamp, or wafer table. The apparatus can include a coating on the top surfaces of the burls and the modified surface is formed in the coating. The coating can be a TiN, CrN, or DLC coating. The burls can include a plurality of hills and the modified surface is on the plurality of hills and the modified surface can include roughened areas formed across the hills.

In yet other variations, the modified surface can include roughened areas having a separation between them. The between roughened areas can be approximately 10 microns, approximately 15 microns, or approximately 20 microns. The modified surface can have an arithmetical mean height (Sa) of between 0.4 nm and 19 nm. The modified surface includes roughened areas where approximately 5 nm of material in at least one of the grain boundaries has been removed.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed implementations. In the drawings,

FIG. 1 is a block diagram of various subsystems of a lithographic projection apparatus, according to an embodiment.

FIG. 2 is an exemplary flow chart for simulating lithography in a lithographic projection apparatus, according to an embodiment.

FIG. 3 is a simplified top view of a wafer resting upon a burl surface of a wafer table, according to an embodiment.

FIG. 4 is a simplified side view of exemplary burls with coatings, according to an embodiment.

FIG. 5 is a simplified diagram of a side sectional view of an exemplary burl having crystalline grains and crystalline grain boundaries, according to an embodiment.

FIG. 6 is a simplified diagram of an exemplary sectional view of a burl receiving light at a native surface formed of crystalline grains and crystalline grain boundaries, according to an embodiment.

FIG. 7 is a simplified diagram of the burl of FIG. 6, roughened to form a modified surface by having a portion of the crystalline grain boundaries ablated, according to an embodiment.

FIG. 8 is a simplified diagram illustrating an exemplary burl having separated roughened areas hilltops formed on the burl, according to an embodiment.

FIG. 9 is a simplified diagram illustrating a roughness map, according to an embodiment.

FIG. 10 is a process flow diagram for controlling a tool to form furrows and ridges, according to an embodiment.

FIG. 11 is a block diagram of an example computer system, according to an embodiment.

FIG. 12 is a schematic diagram of a lithographic projection apparatus, according to an embodiment.

FIG. 13 is a schematic diagram of another lithographic projection apparatus, according to an embodiment.

FIG. 14 is a detailed view of the lithographic projection apparatus, according to an embodiment.

FIG. 15 is a detailed view of the source collector module of the lithographic projection apparatus, according to an embodiment.

### DETAILED DESCRIPTION

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. One or more of the design rule limitations may be referred to as “critical dimension” (CD). A critical dimension of a device can be defined as the smallest width of a line or hole or the smallest space between two lines or two holes. Thus, the CD determines the overall size and density of the designed device. Of course, one of the goals in device fabrication is to faithfully reproduce the original design intent on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include a programmable mirror array and a programmable LCD array.

An example of a programmable mirror array can be a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic methods.

An example of a programmable LCD array is given in U.S. Pat. No. 5,229,872, which is incorporated herein by reference.

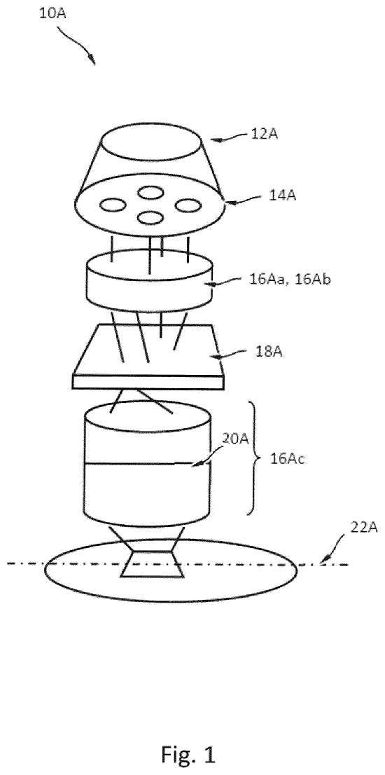

FIG. 1 illustrates a block diagram of various subsystems of a lithographic projection apparatus 10A, according to an embodiment. Major components are a radiation source 12A, which may be a deep-ultraviolet excimer laser source or other type of source including an extreme ultra violet (EUV) source (as discussed above, the lithographic projection apparatus itself need not have the radiation source), illumination optics which, e.g., define the partial coherence (denoted as sigma) and which may include optics 14A, 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(Θₘₐₓ), wherein n is the refractive index of the media between the substrate and the last element of the projection optics, and Θₘₐₓ is the largest angle of the beam exiting from the projection optics that can still impinge on the substrate plane 22A.

In a lithographic projection apparatus, a source provides illumination (i.e. radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. US 2009-0157630, the disclosure of which is hereby incorporated by reference in its entirety. The resist model is related only to properties of the resist layer (e.g., effects of chemical processes which occur during exposure, post-exposure bake (PEB) and development). Optical properties of the lithographic projection apparatus (e.g., properties of the illumination, the patterning device and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety.

One aspect of understanding a lithographic process is understanding the interaction of the radiation and the patterning device. The electromagnetic field of the radiation after the radiation passes the patterning device may be determined from the electromagnetic field of the radiation before the radiation reaches the patterning device and a function that characterizes the interaction. This function may be referred to as the mask transmission function (which can be used to describe the interaction by a transmissive patterning device and/or a reflective patterning device).

The mask transmission function may have a variety of different forms. One form is binary. A binary mask transmission function has either of two values (e.g., zero and a positive constant) at any given location on the patterning device. A mask transmission function in the binary form may be referred to as a binary mask. Another form is continuous. Namely, the modulus of the transmittance (or reflectance) of the patterning device is a continuous function of the location on the patterning device. The phase of the transmittance (or reflectance) may also be a continuous function of the location on the patterning device. A mask transmission function in the continuous form may be referred to as a continuous tone mask or a continuous transmission mask (CTM). For example, the CTM may be represented as a pixelated image, where each pixel may be assigned a value between 0 and 1 (e.g., 0.1, 0.2, 0.3, etc.) instead of binary value of either 0 or 1. In an embodiment, CTM may be a pixelated gray scale image, where each pixel having values (e.g., within a range [−255, 255], normalized values within a range [0, 1] or [−1, 1] or other appropriate ranges).

The thin-mask approximation, also called the Kirchhoff boundary condition, is widely used to simplify the determination of the interaction of the radiation and the patterning device. The thin-mask approximation assumes that the thickness of the structures on the patterning device is very small compared with the wavelength and that the widths of the structures on the mask are very large compared with the wavelength. Therefore, the thin-mask approximation assumes the electromagnetic field after the patterning device is the multiplication of the incident electromagnetic field with the mask transmission function. However, as lithographic processes use radiation of shorter and shorter wavelengths, and the structures on the patterning device become smaller and smaller, the assumption of the thin-mask approximation can break down. For example, interaction of the radiation with the structures (e.g., edges between the top surface and a sidewall) because of their finite thicknesses (“mask 3D effect” or “M3D”) may become significant. Encompassing this scattering in the mask transmission function may enable the mask transmission function to better capture the interaction of the radiation with the patterning device. A mask transmission function under the thin-mask approximation may be referred to as a thin-mask transmission function. A mask transmission function encompassing M3D may be referred to as a M3D mask transmission function.

According to an embodiment of the present disclosure, one or more images may be generated. The images includes various types of signal that may be characterized by pixel values or intensity values of each pixel. Depending on the relative values of the pixel within the image, the signal may be referred as, for example, a weak signal or a strong signal, as may be understood by a person of ordinary skill in the art. The term “strong” and “weak” are relative terms based on intensity values of pixels within an image and specific values of intensity may not limit scope of the present disclosure. In an embodiment, the strong and weak signal may be identified based on a selected threshold value. In an embodiment, the threshold value may be fixed (e.g., a midpoint of a highest intensity and a lowest intensity of pixel within the image. In an embodiment, a strong signal may refer to a signal with values greater than or equal to an average signal value across the image and a weak signal may refer to signal with values less than the average signal value. In an embodiment, the relative intensity value may be based on percentage. For example, the weak signal may be signal having intensity less than 50% of the highest intensity of the pixel (e.g., pixels corresponding to target pattern may be considered pixels with highest intensity) within the image. Furthermore, each pixel within an image may considered as a variable. According to the present embodiment, derivatives or partial derivative may be determined with respect to each pixel within the image and the values of each pixel may be determined or modified according to a cost function based evaluation and/or gradient based computation of the cost function. For example, a CTM image may include pixels, where each pixel is a variable that can take any real value.

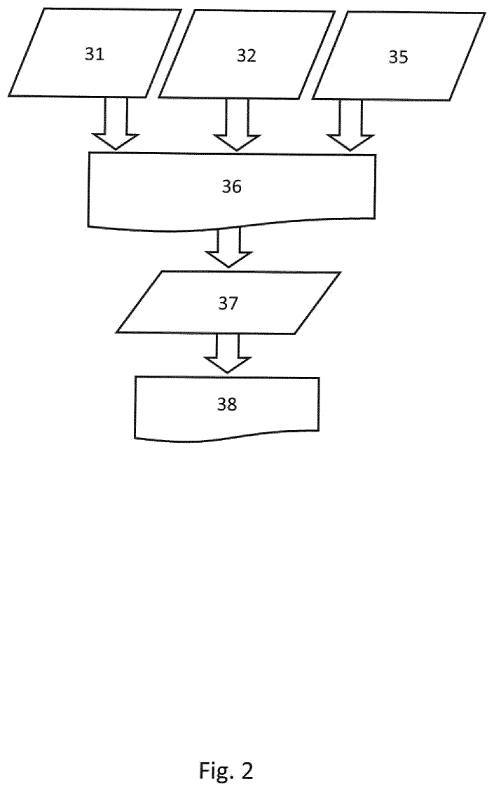

FIG. 2 illustrates an exemplary flow chart for simulating lithography in a lithographic projection apparatus, according to an embodiment. Source model 31 represents optical characteristics (including radiation intensity distribution and/or phase distribution) of the source. Projection optics model 32 represents optical characteristics (including changes to the radiation intensity distribution and/or the phase distribution caused by the projection optics) of the projection optics. Design layout model 35 represents optical characteristics of a design layout (including changes to the radiation intensity distribution and/or the phase distribution caused by design layout 33), which is the representation of an arrangement of features on or formed by a patterning device. Aerial image 36 can be simulated from design layout model 35, projection optics model 32, and design layout model 35. Resist image 38 can be simulated from aerial image 36 using resist model 37. Simulation of lithography can, for example, predict contours and CDs in the resist image.

More specifically, it is noted that source model 31 can represent the optical characteristics of the source that include, but not limited to, numerical aperture settings, illumination sigma (σ) settings as well as any particular illumination shape (e.g. off-axis radiation sources such as annular, quadrupole, dipole, etc.). Projection optics model 32 can represent the optical characteristics of the projection optics, including aberration, distortion, one or more refractive indexes, one or more physical sizes, one or more physical dimensions, etc. Design layout model 35 can represent one or more physical properties of a physical patterning device, as described, for example, in U.S. Pat. No. 7,587,704, which is incorporated by reference in its entirety. The objective of the simulation is to accurately predict, for example, edge placement, aerial image intensity slope and/or CD, which can then be compared against an intended design. The intended design is generally defined as a pre-OPC design layout which can be provided in a standardized digital file format such as GDSII or OASIS or other file format.

From this design layout, one or more portions may be identified, which are referred to as “clips”. In an embodiment, a set of clips is extracted, which represents the complicated patterns in the design layout (typically about 50 to 1000 clips, although any number of clips may be used). These patterns or clips represent small portions (i.e. circuits, cells or patterns) of the design and more specifically, the clips typically represent small portions for which particular attention and/or verification is needed. In other words, clips may be the portions of the design layout, or may be similar or have a similar behavior of portions of the design layout, where one or more critical features are identified either by experience (including clips provided by a customer), by trial and error, or by running a full-chip simulation. Clips may contain one or more test patterns or gauge patterns.

An initial larger set of clips may be provided a priori by a customer based on one or more known critical feature areas in a design layout which require particular image optimization. Alternatively, in another embodiment, an initial larger set of clips may be extracted from the entire design layout by using some kind of automated (such as machine vision) or manual algorithm that identifies the one or more critical feature areas.

In a lithographic projection apparatus, as an example, a cost function may be expressed as

CF(z₁,z₂, . . . ,z_{N})=Σₚ₌₁^{P}wₚfₚ²(z₁,z₂, . . . ,z_{N}) (Eq. 1)

where (z₁, z₂, . . . , z_{N}) are N design variables or values thereof. fₚ (z₁, z₂, . . . , z_{N}) can be a function of the design variables (z₁, z₂, . . . , z_{N}) such as a difference between an actual value and an intended value of a characteristic for a set of values of the design variables of (z₁, z₂, . . . , z_{N}). wₚ is a weight constant associated with fₚ (z₁, z₂, . . . , z_{N}). For example, the characteristic may be a position of an edge of a pattern, measured at a given point on the edge. Different fₚ (z₁, z₂, . . . , z_{N}) may have different weight wₚ. For example, if a particular edge has a narrow range of permitted positions, the weight wₚ for the fₚ (z₁, z₂, . . . , z_{N}) representing the difference between the actual position and the intended position of the edge may be given a higher value. fₚ (z₁, z₂, . . . , z_{N}) can also be a function of an interlayer characteristic, which is in turn a function of the design variables (z₁, z₂, . . . , z_{N}). Of course, CF (z₁, z₂, . . . , z_{N}) is not limited to the form in Eq. 1. CF(z₁, z₂, . . . , z_{N}) can be in any other suitable form.

The cost function may represent any one or more suitable characteristics of the lithographic projection apparatus, lithographic process or the substrate, for instance, focus, CD, image shift, image distortion, image rotation, stochastic variation, throughput, local CD variation, process window, an interlayer characteristic, or a combination thereof. In one embodiment, the design variables (z₁, z₂, . . . , z_{N}) comprise one or more selected from dose, global bias of the patterning device, and/or shape of illumination. Since it is the resist image that often dictates the pattern on a substrate, the cost function may include a function that represents one or more characteristics of the resist image. For example, fₚ (z₁, z₂, . . . , z_{N}) can be simply a distance between a point in the resist image to an intended position of that point (i.e., edge placement error EPEₚ(z₁, z₂, . . . , z_{N}). The design variables can include any adjustable parameter such as an adjustable parameter of the source, the patterning device, the projection optics, dose, focus, etc.

The lithographic apparatus may include components collectively called a “wavefront manipulator” that can be used to adjust the shape of a wavefront and intensity distribution and/or phase shift of a radiation beam. In an embodiment, the lithographic apparatus can adjust a wavefront and intensity distribution at any location along an optical path of the lithographic projection apparatus, such as before the patterning device, near a pupil plane, near an image plane, and/or near a focal plane. The wavefront manipulator can be used to correct or compensate for certain distortions of the wavefront and intensity distribution and/or phase shift caused by, for example, the source, the patterning device, temperature variation in the lithographic projection apparatus, thermal expansion of components of the lithographic projection apparatus, etc. Adjusting the wavefront and intensity distribution and/or phase shift can change values of the characteristics represented by the cost function. Such changes can be simulated from a model or actually measured. The design variables can include parameters of the wavefront manipulator.

The design variables may have constraints, which can be expressed as (z₁, z₂, . . . , z_{N})∈Z, where Z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. For example, if the dose is a design variable, without such a constraint, the optimization may yield a dose value that makes the throughput economically impossible. However, the usefulness of constraints should not be interpreted as a necessity. For example, the throughput may be affected by the pupil fill ratio. For some illumination designs, a low pupil fill ratio may discard radiation, leading to lower throughput. Throughput may also be affected by the resist chemistry. Slower resist (e.g., a resist that requires higher amount of radiation to be properly exposed) leads to lower throughput.

As used herein, the term “patterning process” means a process that creates an etched substrate by the application of specified patterns of light as part of a lithography process.

As used herein, the term “imaging device” means any number or combination of devices and associated computer hardware and software that can be configured to generate images of a target, such as the printed pattern or portions thereof, or of any surfaces and features as described throughout the specification. Non-limiting examples of an imaging devices can include: scanning electron microscopes (SEMs), atomic force microscopes (AFMs), x-ray machines, optical microscopes, etc.

Some lithography processes include, for example, using a reticle (or mask) to provide a specific pattern of light at a photoresist to create a pattern for etching onto a wafer. To hold the reticle and wafer in place, clamping devices can be used. Because it is important to the manufacturing process that the surfaces involved be very flat, an undesirable consequence can be that reticle can stick to the reticle clamp, the wafer can stick to the wafer clamp or wafer table where the wafer rests, etc. This sticking can cause damage to the wafer, reticle, clamps, etc. The sticking mechanism can include the forming of van der Waals bonds between the components along the contact surfaces. Accordingly, embodiments of the disclosed subject matter address the problem of sticking by, among other things, reducing the total van der Waals forces between the objects by, for example, reducing the contact area between components, thus making sticking less likely to occur.

One way of reducing the contact surface area is to make the contact surface rougher such that only the higher portions of the roughened surface come into contact with the wafer or reticle. As described further below, the surface to be roughened can be made of a combination of crystalline and amorphous materials. As one example, a laser can be used to deliver a specific amount of energy to the surface such that the amorphous material is ablated, while the crystalline material is not ablated or ablated significantly less. This selective ablation reduces the contact surface area by only making it possible for the wafer or reticle to come in contact with the remaining crystalline material. By varying the laser energy and the pattern of delivery of the laser to the surface, different degrees of roughness and patterns of roughness can be formed.

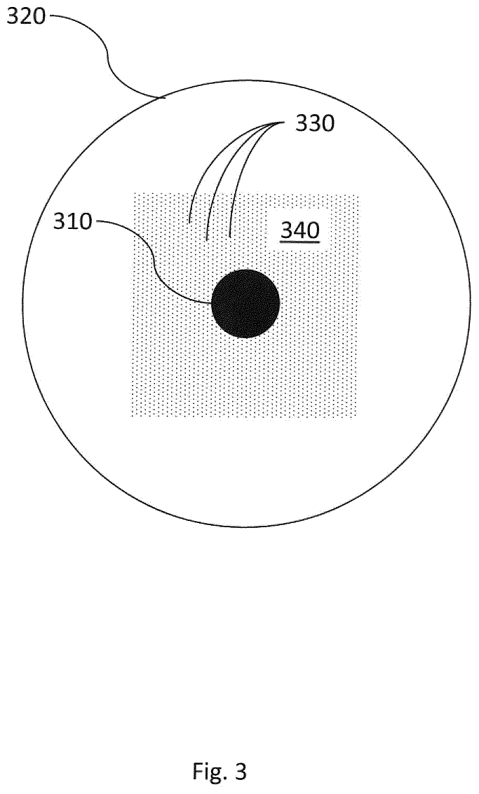

FIG. 3 illustrates a simplified top view of a wafer 310 resting upon a burl surface 340 of a wafer table 320, according to an embodiment.

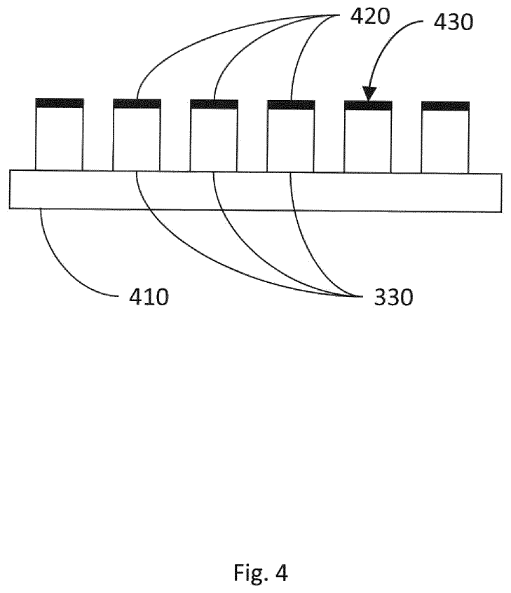

Wafer table 320 is shown with a number of burls 330 that combine to form burl surface 340. An example wafer 310 can rest upon burl surface 340. As illustrated further in FIG. 4, burls, as used herein, can include any material features that extend from a substrate, such as a wafer table 320, wafer clamp, reticle clamp, etc. to support a wafer 310 or reticle.

Burls can provide some nominal separation (and reduction of contact surface area) between wafer 310 and wafer table 320. For example, by supporting wafer 310 on burl surface 340 (which can be made up of a number of burls 330 having some separation between them), the above-described van der Waals forces can be reduced as well as the avoidance of vacuums, air pockets, etc.

The embodiments described herein generally refer to a wafer resting upon wafer table. However, such description is not intended to be limiting. For example, rather than wafers and wafer tables, aspects of the present disclosure can also be applied to other components (e.g., reticles in contact with reticle clamps), as well as the wafer resting on burls of any type, number, and geometry having an associated burl surface.

FIG. 4 illustrates a simplified side view of burls 330 with coatings 420, according to an embodiment.

The side view illustrated in FIG. 4, shows a number of exemplary burls 330 extending from substrate 410. In some embodiments, as shown, burls 330 can include a coating 420, which may be a hard ceramic coating, provided on at least a top surface of the burls 330. Coatings 420 can include, for example, Titanium Nitride (TiN), Chromium Nitride (CrN), Diamond-like Carbon (DLC), Tantalum (Ta), Tantalum Boride (TaB), Tungsten (W), Tungsten Carbide (WC), Boron Nitride (BN), etc. Such coatings can be added to burls 330 to protect the burl structure underneath. As used herein, the term “burl surface” (e.g., burl surface 430 in FIG. 4) can refer to either a top surface of a burl 330 when there is no coating 420, or to a top surface of coating 420 when such coating 420 is present on burl 330.

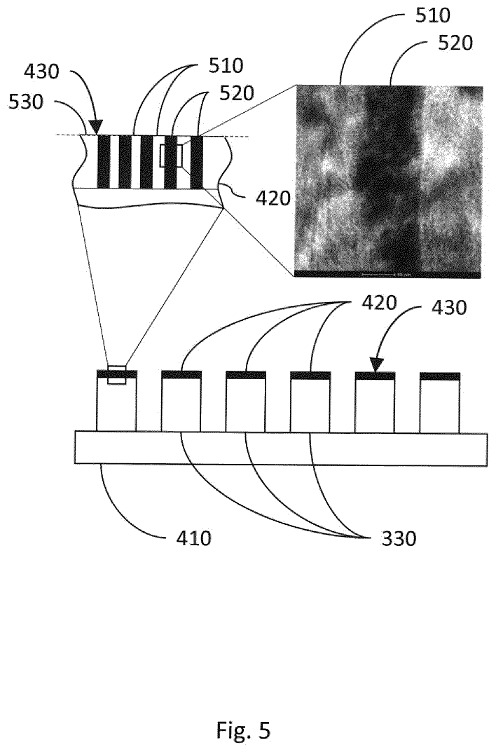

As discussed throughout the present disclosure, surfaces that are candidates for roughening can include the tops of burls (e.g., the substrate of the burl itself), a coating, or any other suitable surface which may exhibit sticking during use. FIG. 5 illustrates a side view of an example burl top. One expanded portion of a cross-section of a burl is shown in the upper left. As described herein, some materials can have portions that are more easily removed (such as by laser ablation) than others. For example, the illustrated burl coating can have a semi-crystalline structure can include crystalline grains 510 and softer material between the crystalline grains (referred to herein as crystalline grain boundaries 520). In FIG. 5, the light vertical bands are simplified representation of hard crystalline grains and the dark vertical bands are a simplified representation of a softer crystalline grain boundary.

A further expanded view of a portion of the burl section is shown in the upper right portion of FIG. 5, illustrating an example transmission electron microscope image of the vertical crystalline grains 510 (lightly colored) and the crystalline grain boundaries 520 (darker colored and located in between the crystalline grains 510).

As used herein, the term “native surface” means a surface that exists prior to a given roughening procedure (resulting in a “modified surface,” discussed below). A simplified example of the native surface 530 is illustrated by the dashed line in the simplified sectional view of the burl top.

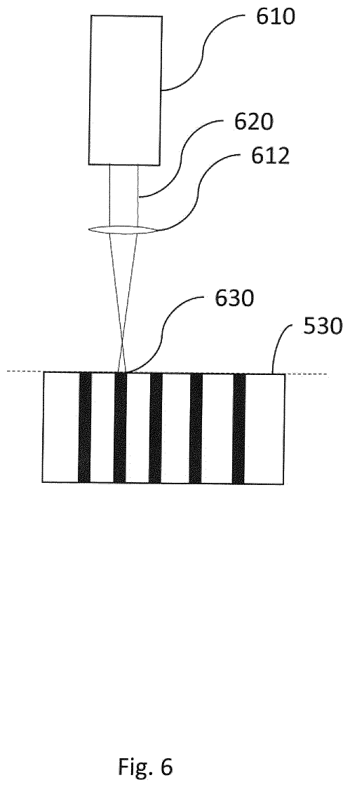

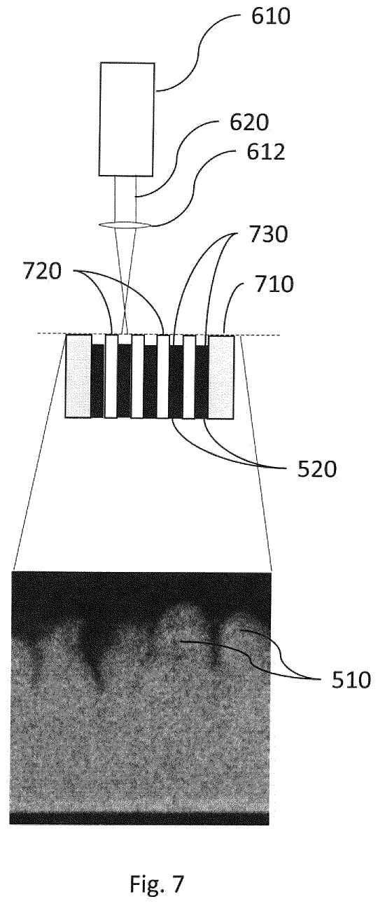

FIGS. 6 and 7 illustrate a method for reducing sticking of an object (e.g., a reticle) to a modified surface (e.g., a roughened surface of a reticle clamp, illustrated for example in FIG. 7). In some cases, this can be a modified surface used to support the object in a lithography process. As shown in FIG. 6, one example method of reducing sticking can include controlling a light source (e.g., a laser) to deliver light 620 to a native surface 610 (e.g., part of a top surface of a burl) thereby causing ablation of at least a portion of the native surface to increase the roughness of the native surface thereby forming the modified surface (e.g., as shown in FIG. 7). Because ablating a portion of the surface that can come into contact with an object can reduce the contact surface area, the increased roughness reduces the ability of the object to stick to the modified surface.

As used herein, the term “modified surface” means a surface that has been roughened relative to the prior state by any of the methods disclosed herein. For simplicity, the instant disclosure often refers to a “native surface” that is roughened to become a modified surface. However, a modified surface can also result from any surface that has already been treated by the disclosed methods or by other methods. For example, multiple applications of the roughening process described herein can result in a modified surface where a surface is first modified (roughened) and then roughened again to form yet a further modified surface. Also, as another example, a surface can be cut, polished, sanded, etc. before application of any of the disclosed methods that “modifies” this initial or “native” surface.

Because the native surface can include crystalline grains separated by grain boundaries by selecting an energy density of the light source that oblates the grain boundary, but is not sufficient to ablate the crystalline grains, a selective ablation of the native surface can be performed that has the effect of roughening the native surface.

Accordingly, some embodiments can include setting an energy density of the light source to generate light having a fluence at the native surface that, when delivered to the surface, causes selective ablation of the native surface based on an atomic structure of the native surface. In this way, the selective ablation can reduce a surface area for contacting the object and thereby reduce the sticking between the object and the modified surface.

This can be performed by, for example, removing material of the grain boundaries and while causing essentially no ablation of the crystalline grains. As used herein, when describing that there is “essentially” no ablation of the crystalline grains, this is intended to mean that there is significantly less ablation of the crystalline grains than of the grain boundaries. For example, the amount of completion of the crystalline grains may be less than 10% or less than 1% of the corresponding ablation of crystalline grain boundaries that receive the same energy density of the light.

The present disclosure contemplates different methods by which the energy density used for ablation can be set. For example, the light source can be controlled to adjust one or more of an intensity and/or focus of the light source to set the energy density based on a desired roughness of the modified surface. Adjusting and intensity of the light source can include turning up the power of the light source, adding additional light sources to combine the light at the modified surface.

As illustrated in FIG. 6, a focus 630 of the light source can be adjusted (e.g., increased or decreased) such that the spot formed by the light source changes, thus increasing or reducing the energy density. As used herein, the term “focus” means the degree to which the light source is focused at the native surface. In general, the energy density is a maximum when the light from the light source is most focused at the surface. In the example of FIG. 6, where the position of the surface moved relative to the light source (either by moving the burl/burl surface or by moving lens 612) the focus would change. Also, as shown, the light source is slightly out of focus, resulting in an energy density which would be less than the maximum density if the surface was at the illustrated focal point. Focus is also related to spot size because, in general, the spot size at a surface is a minimum when the light source is focused on the surface.

Also, as used herein, when referring to the “light source” is understood that this includes not just the laser source itself, but also any intervening optical elements between the laser source and surface. These optical elements can include, for example, mirrors, filters, lenses, etc.

FIG. 7 illustrates a simplified example of a modified surface 710 resulting from the roughening methods described herein. FIG. 7 is similar to FIG. 6 and that the light source 610 and the exemplary section of a burl top is shown. However, the shown example illustrates the ablated crystalline boundary material 520 and thus the modified surface 710 has some portions being below the initial native surface 530.

The surfaces described herein can be formed on objects or apparatuses used in a lithography process but may also be formed on any other objects or apparatuses for applications that can benefit from the disclosed methods. As such, the modified surface can be part of an apparatus where the modified surface can be configured to contact an object. The modified surface of such an apparatus can be formed from a material having a grain structure including crystalline grains and grain boundaries. As shown in FIG. 7, the modified surface can have a roughness based at least on crystalline grain peaks and crystalline grain boundary valleys located below the crystalline grain peaks. In the specific example shown in FIG. 6, before roughening, the native surface 530 had an area (though shown from the side and indicated by the dashed line) that included both crystalline grains and grain boundaries. In FIG. 7, after roughening, some of the grain boundary material has been ablated, forming crystalline grain peaks 720 and crystalline grain boundary valleys 730. As such, the modified surface 710 (again indicated by the dashed line) that would contact an object does not include the crystalline grain boundary material (e.g., crystalline grain boundary valleys 730). Therefore, in general, the contact surface area at the modified surface can be less than what it was before the roughening process.

The lower portion of FIG. 7 illustrates an example of a TEM image corresponding to simplified diagram of the upper portion of FIG. 7. Here, the lighter colored material represents the crystalline grains 510 (which have a column-like structure in this example). As can be seen, some material (e.g., the grain boundary material) has been removed from between the crystalline grains. Accordingly, the increase in roughness is apparent in this image as well as reduced contact surface area of the modified surface.

In some embodiments, in at least one location on the modified surface, between 2 nm and 30 nm of grain boundary material was removed from the native surface. Also, in other embodiments, the modified surface can include roughened areas where approximately 5 nm of material in at least one of the grain boundaries has been removed. In yet other embodiments, the modified surface can have an arithmetical mean height (Sa) of between 0.4 nm and 19 nm. As used herein, “roughness” can refer to the arithmetical mean height or an RMS roughness of a portion of the modified surface.

In some embodiments, the roughness can be the root-mean-square of height of the modified surface and can be between 3 and 35 nm, or between 20 and 35 nm. Therefore, in various embodiments, the roughness of the modified surface can be greater than 2 nm and the roughness of the native surface can be less than 3 nm.

As the ablation of the grain boundary material can be a function of the energy density of the light delivered at the surface, the surface roughness can be expressed in terms of a ratio of energy densities. Specifically, in some examples, an energy density ratio of 1.0 (for a given light source output, spot size, etc.) can result in a surface roughness of approximately 20 nm, an energy density ratio of 1.05 resulting in a surface roughness of approximately 25 nm, and an energy density ratio of 1.15 resulting in a surface roughness of approximately 30 nm.

The roughening processes described herein can result in a number of useful apparatuses that exhibit reduced sticking. For example, the apparatus can include a number of burls extending from a substrate (e.g., a reticle clamp, wafer clamp, or wafer table), where the modified surface is on top surfaces of the burls. In such embodiments, the burls can be, for example, Si or SiC, and can optionally have a coating (e.g., Ti, Cr, or DLC) applied to the top surfaces of the burls such that the modified surface can be formed in the coating to reflect the roughened burl underneath the coating.

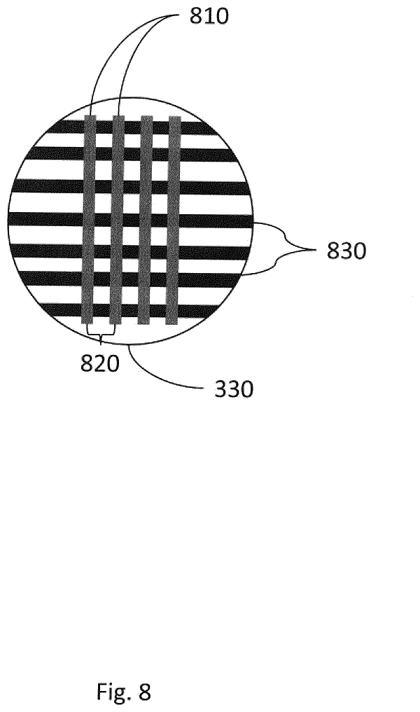

In other embodiments of the present disclosure, roughening can be applied in a variety of patterns at some macroscopic scale. This can be considered as “low-frequency roughening,” as opposed to “high-frequency roughening” that would be more descriptive of the smaller-scale ablated areas caused by removal of the crystalline grain boundary material. The low-frequency roughening can be performed by controlling the light source to deliver light at separated locations 810 on the native surface causing ablation of a portion of the grain boundaries. In this way, the delivering of the light can cause the modified surface to comprise roughened areas having a separation 820 between them. These separated roughened areas (shown in FIG. 8 by the grey bands) can take the form of, for example, a series of parallel lines, cross lines (e.g., similar to a checkerboard pattern), a spiral pattern, etc. One example of such separated locations is illustrated on the example burl shown in FIG. 8.

In some embodiments, the burl 330 can (for example that is part of a reticle clamp) include hills 830 formed on the burl 330 or burl coating. Hills formed in the burls can be, for example, approximately 10 μm wide, spaced 10 μm apart from each other, and have a height of between 80 to 120 nm. In this example, the light source can be controlled to deliver light across hilltops of the hills formed on top surfaces of the burls, forming the modified surface on the hills. As used with regard to delivering light across hilltops (or any other features of the burls), the term “across” means approximately perpendicular to a hill direction. However, in other embodiments, the approximate angle of the path of the light can be, for example, 90 degrees, 80 degrees, 60 degrees, 45 degrees, 30 degrees, 15 degrees, etc. In this way, it the light path across hilltops formed in the surface can potentially intersect multiple hilltops to form a secondary roughening feature. In still other embodiments, the roughening can be performed on the hilltops (e.g., approximately parallel to the hilltops), in order to add roughened areas as described herein.

The separation between roughened areas can vary. In some embodiments, the separation between roughened areas on the modified surface can be approximately 2, 5, 10, 15, 20, or 30 μm. As illustrated in FIG. 8, the separation 820 can be greater than a spot size (represented by the width of the grey bands) of the light source, such that the roughened areas do not overlap. In other embodiments, the separation between locations of the delivery of light can be less than the spot size of the light source, which can result in some degree of overlap in locations receiving the light. In such embodiments, there can be additional roughening in the overlapped areas, for example, due to the multiple applications of energy to the grain boundary material at those overlapped areas.

While embodiments of the present disclosure are discussed with reference to materials that have a crystalline structure with software crystalline grain boundaries suitable for ablation, the methods and resulting apparatuses described herein can be used with other materials and in other applications. For example, it is not necessary that the material has a strict crystalline structure. Instead, any suitable material that permits the preferential or selective ablation of some regions when exposed to light can be used, or be the recipient of, the disclosed methods.

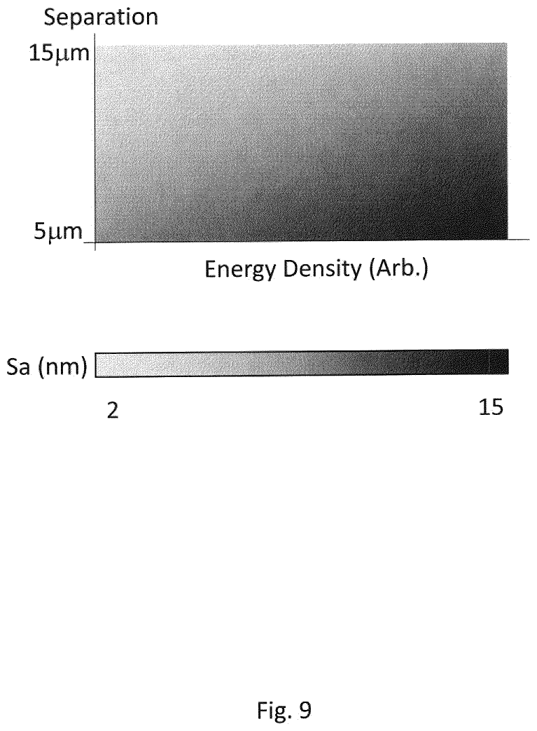

By applying the methods described herein, the roughness of a surface (e.g., a burl top) can be engineered by the controlled application of light to a native surface. As previously discussed, this can be a function of a) separation or line spacing between locations where the light is delivered, and b) the energy density of the light at the native surface. This can essentially provide a roughness map that can be delivered upon execution of specific programming instructions to the light source. One simplified example of such a roughness map is illustrated in FIG. 9. The roughness is schematically represented by the shading, and in this example, ranges from a Sa of 2 to 15 nm. As shown, the roughness increases with decreasing line spacing (as there are less gaps between roughened areas). Also, roughness increases with increasing energy density (as more of the crystalline grain boundary is removed). In this way, consistent with certain aspects of the present disclosure, a roughness can be selected by a user, and separation between roughened areas and the energy density delivered by the light source can be specified. There can be similar roughness maps generated for different burl materials, different coatings, etc. Accordingly, variations of the example roughness map are contemplated, and the specific roughness values and indicated separation between where the light is delivered should not be considered limiting.

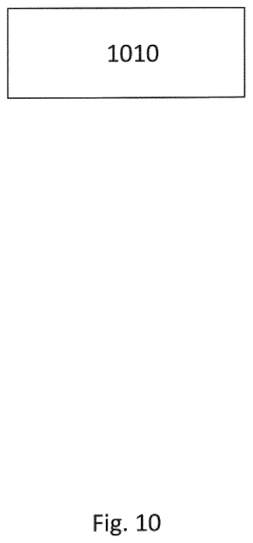

One example method of reducing sticking of an object to a modified surface (e.g., as used to support the object in a lithography process) is illustrated in FIG. 10. In this embodiment, the method includes controlling a light source to deliver light to a native surface thereby causing ablation of at least a portion of the native surface to increase the roughness of the native surface thereby forming the modified surface, where the increased roughness reduces the ability of the object to stick to the modified surface.

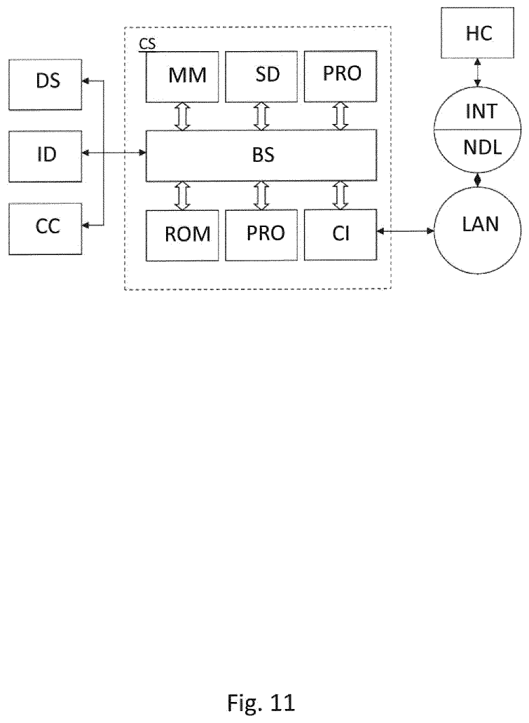

FIG. 11 is a block diagram of an example computer system CS, according to an embodiment. Computer system CS includes a bus BS or other communication mechanism for communicating information, and a processor PRO (or multiple processor) coupled with bus BS for processing information. Computer system CS also includes a main memory MM, such as a random-access memory (RAM) or other dynamic storage device, coupled to bus BS for storing information and instructions to be executed by processor PRO. Main memory MM also may be used for storing temporary variables or other intermediate information during execution of instructions to be executed by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions contained in main memory MM causes processor PRO to perform the process steps described herein. One or more processors in a multi-processing arrangement may also be employed to execute the sequences of instructions contained in main memory MM. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the features described herein. Transitory computer-readable media can include a carrier wave or other propagating electromagnetic signal.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) both use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

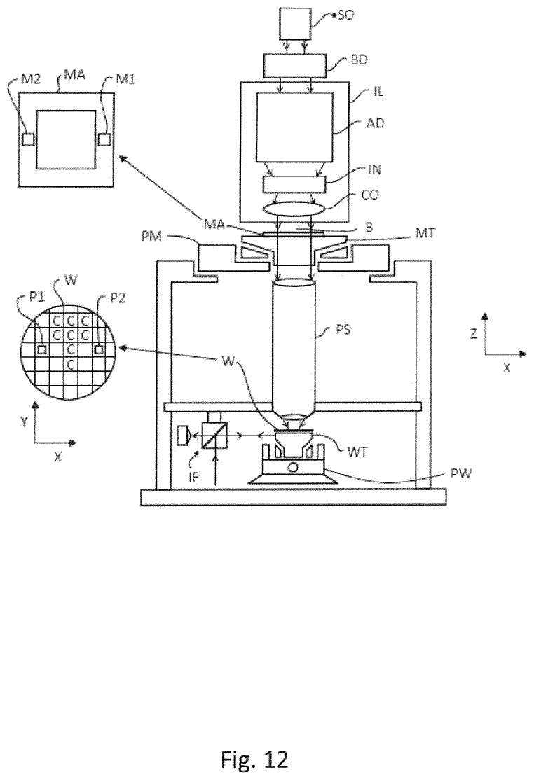

FIG. 12 is a schematic diagram of a lithographic projection apparatus, according to an embodiment.

The lithographic projection apparatus can include an illumination system IL, a first object table MT, a second object table WT, and a projection system PS.

Illumination system IL, can condition a beam B of radiation. In this particular case, the illumination system also comprises a radiation source SO.

First object table (e.g., patterning device table) MT can be provided with a patterning device holder to hold a patterning device MA (e.g., a reticle), and connected to a first positioner to accurately position the patterning device with respect to item PS.

Second object table (substrate table) WT can be provided with a substrate holder to hold a substrate W (e.g., a resist-coated silicon wafer), and connected to a second positioner to accurately position the substrate with respect to item PS.

Projection system (“lens”) PS (e.g., a refractive, catoptric or catadioptric optical system) can image an irradiated portion of the patterning device MA onto a target portion C (e.g., comprising one or more dies) of the substrate W.

As depicted herein, the apparatus can be of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning apparatuses, such as a beam expander Ex, for example. The illuminator IL may comprise adjusting device AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus, the radiation beam that it produces being led into the apparatus (e.g., with the aid of suitable directing mirrors); this latter scenario can be the case when source SO is an excimer laser (e.g., based on KrF, ArF or F2 lasing).

The beam PB can subsequently intercept patterning device MA, which is held on a patterning device table MT. Having traversed patterning device MA, the beam B can pass through the lens PL, which focuses beam B onto target portion C of substrate W. With the aid of the second positioning apparatus (and interferometric measuring apparatus IF), the substrate table WT can be moved accurately, e.g. so as to position different target portions C in the path of beam PB. Similarly, the first positioning apparatus can be used to accurately position patterning device MA with respect to the path of beam B, e.g., after mechanical retrieval of the patterning device MA from a patterning device library, or during a scan. In general, movement of the object tables MT, WT can be realized with the aid of a long-stroke module (coarse positioning) and a short-stroke module (fine positioning). However, in the case of a stepper (as opposed to a step-and-scan tool) patterning device table MT may just be connected to a short stroke actuator, or may be fixed.

The depicted tool can be used in two different modes, step mode and scan mode. In step mode, patterning device table MT is kept essentially stationary, and an entire patterning device image is projected in one go (i.e., a single “flash”) onto a target portion C. Substrate table WT can be shifted in the x and/or y directions so that a different target portion C can be irradiated by beam PB.

In scan mode, essentially the same scenario applies, except that a given target portion C is not exposed in a single “flash.” Instead, patterning device table MT is movable in a given direction (the so-called “scan direction”, e.g., the y direction) with a speed v, so that projection beam B is caused to scan over a patterning device image; concurrently, substrate table WT is simultaneously moved in the same or opposite direction at a speed V=Mv, in which M is the magnification of the lens PL (typically, M=¼ or ⅕). In this manner, a relatively large target portion C can be exposed, without having to compromise on resolution.

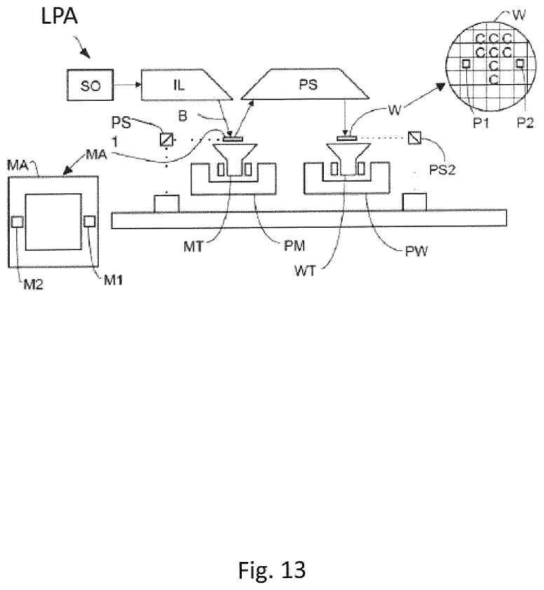

FIG. 13 is a schematic diagram of another lithographic projection apparatus (LPA), according to an embodiment.

LPA can include source collector module SO, illumination system (illuminator) IL configured to condition a radiation beam B (e.g. EUV radiation), support structure MT, substrate table WT, and projection system PS.

Support structure (e.g. a patterning device table) MT can be constructed to support a patterning device (e.g. a mask or a reticle) MA and connected to a first positioner PM configured to accurately position the patterning device;

Substrate table (e.g. a wafer table) WT can be constructed to hold a substrate (e.g. a resist coated wafer) W and connected to a second positioner PW configured to accurately position the substrate.

Projection system (e.g. a reflective projection system) PS can be configured to project a pattern imparted to the radiation beam B by patterning device MA onto a target portion C (e.g. comprising one or more dies) of the substrate W.

As here depicted, LPA can be of a reflective type (e.g. employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has a 40 layer pairs of molybdenum and silicon where the thickness of each layer is a quarter wavelength.

Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultra violet radiation beam from source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. Source collector module SO may be part of an EUV radiation system including a laser for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser may not be considered to form part of the lithographic apparatus and the radiation beam can be passed from the laser to the source collector module with the aid of a beam delivery system comprising, for example, suitable directing mirrors and/or a beam expander. In other cases, the source may be an integral part of the source collector module, for example when the source is a discharge produced plasma EUV generator, often termed as a DPP source.

Illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of radiation beam B. Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus LPA could be used in at least one of the following modes, step mode, scan mode, and stationary mode.

In step mode, the support structure (e.g. patterning device table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.

In scan mode, the support structure (e.g. patterning device table) MT and the substrate table WT are scanned synchronously while a pattern imparted to the radiation beam is projected onto target portion C (i.e. a single dynamic exposure). The velocity and direction of substrate table WT relative to the support structure (e.g. patterning device table) MT may be determined by the (de-)magnification and image reversal characteristics of the projection system PS.

In stationary mode, the support structure (e.g. patterning device table) MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array.

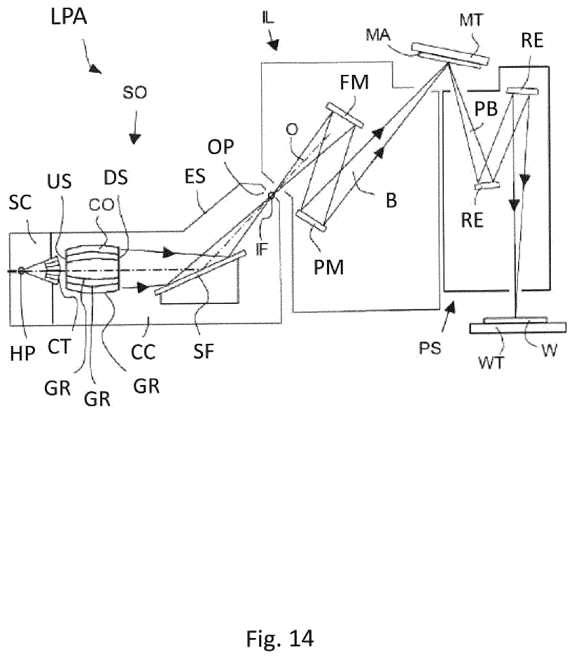

FIG. 14 is a detailed view of the lithographic projection apparatus, according to an embodiment.

As shown, LPA can include the source collector module SO, the illumination system IL, and the projection system PS. The source collector module SO is constructed and arranged such that a vacuum environment can be maintained in an enclosing structure ES of the source collector module SO. An EUV radiation emitting hot plasma HP may be formed by a discharge produced plasma source. EUV radiation may be produced by a gas or vapor, for example Xe gas, Li vapor or Sn vapor in which the hot plasma HP is created to emit radiation in the EUV range of the electromagnetic spectrum. The hot plasma HP is created by, for example, an electrical discharge causing at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma HP is passed from a source chamber SC into a collector chamber CC via an optional gas barrier or contaminant trap CT (in some cases also referred to as contaminant barrier or foil trap) which is positioned in or behind an opening in source chamber SC. The contaminant trap CT may include a channel structure. Contamination trap CT may also include a gas barrier or a combination of a gas barrier and a channel structure. The contaminant trap or contaminant barrier CT further indicated herein at least includes a channel structure, as known in the art.

The collector chamber CC may include a radiation collector CO which may be a so-called grazing incidence collector. Radiation collector CO has an upstream radiation collector side US and a downstream radiation collector side DS. Radiation that traverses radiation collector CO can be reflected off a grating spectral filter SF to be focused in a virtual source point IF along the optical axis indicated by the dot-dashed line ‘0’. The virtual source point IF can be referred to as the intermediate focus, and the source collector module can be arranged such that the intermediate focus IF is located at or near an opening OP in the enclosing structure ES. The virtual source point IF is an image of the radiation emitting plasma HP.

Subsequently the radiation traverses the illumination system IL, which may include a facetted field mirror device FM and a facetted pupil mirror device pm arranged to provide a desired angular distribution of the radiation beam B, at the patterning device MA, as well as a desired uniformity of radiation amplitude at the patterning device MA. Upon reflection of the beam of radiation B at the patterning device MA, held by the support structure MT, a patterned beam PB is formed and the patterned beam PB is imaged by the projection system PS via reflective elements RE onto a substrate W held by the substrate table WT.

More elements than shown may generally be present in illumination optics unit IL and projection system PS. The grating spectral filter SF may optionally be present, depending upon the type of lithographic apparatus. Further, there may be more mirrors present than those shown in the figures, for example there may be 1-6 additional reflective elements present in the projection system PS.

Collector optic CO can be a nested collector with grazing incidence reflectors GR, just as an example of a collector (or collector mirror). The grazing incidence reflectors GR are disposed axially symmetric around the optical axis O and a collector optic CO of this type may be used in combination with a discharge produced plasma source, often called a DPP source.

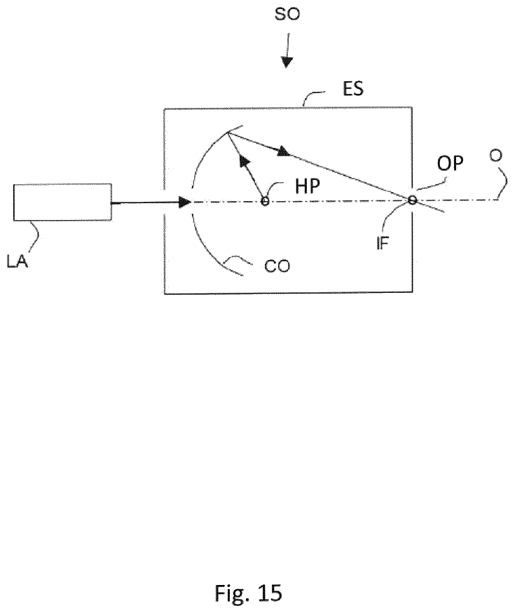

FIG. 15 is a detailed view of source collector module SO of lithographic projection apparatus LPA, according to an embodiment.

Source collector module SO may be part of an LPA radiation system. A laser LA can be arranged to deposit laser energy into a fuel, such as xenon (Xe), tin (Sn) or lithium (Li), creating the highly ionized plasma HP with electron temperatures of several 10's of eV. The energetic radiation generated during de-excitation and recombination of these ions is emitted from the plasma, collected by a near normal incidence collector optic CO and focused onto the opening OP in the enclosing structure ES.

The embodiments may further be described using the following clauses:

1. A method for reducing sticking of an object to a modified surface, the modified surface used to support the object in a lithography process, the method comprising:
controlling a light source to deliver light to a native surface thereby causing ablation of at least a portion of the native surface to increase the roughness of the native surface thereby forming the modified surface, wherein the increased roughness reduces the ability of the object to stick to the modified surface.
   2. The method of clause 1, wherein the light source is a laser.
   3. The method of clause 1, wherein the native surface comprises a top surface of a burl.
   4. The method of clause 1, the controlling comprising:
setting an energy density of the light source to generate light having a fluence at the native surface that, when delivered to the surface, causes selective ablation of the native surface based on an atomic structure of the native surface, the selective ablation reducing a surface area for contacting the object.
   5. The method of clause 4, the native surface comprising crystalline grains separated by grain boundaries, wherein the selective ablation removes material of the grain boundaries and causes essentially no ablation of the crystalline grains.
   6. The method of clause 4, the controlling further comprising:

adjusting one or more of an intensity and/or focus of the light source to set the energy density based on a desired roughness of the modified surface.

7. The method of clause 1, the controlling further comprising:
delivering light at separated locations on the native surface causing ablation of a portion of the grain boundaries, the delivering causing the modified surface to comprise roughened areas having a separation between them.
   8. The method of clause 7, wherein the separation is greater than a spot size of the light source.
   9. The method of clause 1, wherein a separation between locations of the delivery of light can be less than a spot size of the light source.
   10. The method of clause 1, wherein the delivering of light is across a plurality of hilltops on a top surface of a burl forming part of a reticle clamp.
   11. A non-transitory machine-readable medium storing instructions which, when executed by at least one programmable processor, cause the at least one programmable processor to perform operations comprising:
controlling a light source to deliver light to a native surface thereby causing ablation of at least a portion of the native surface to increase the roughness of the native surface thereby forming a modified surface, wherein the increased roughness reduces the ability of an object to stick to the modified surface.
   12. The non-transitory machine-readable medium of clause 11, the controlling comprising:
setting an energy density of the light source to generate light having a fluence at the native surface that, when delivered to the surface, causes selective ablation of the native surface based on an atomic structure of the native surface, the selective ablation reducing a surface area for contacting the object.
   13. The non-transitory machine-readable medium of clause 12, the controlling further comprising:
adjusting one or more of an intensity and/or focus of the light source to set the energy density based on a desired roughness of the modified surface.
   14. The non-transitory machine-readable medium of clause 11, the controlling further comprising:
delivering light at separated locations on the native surface causing ablation of a portion of the grain boundaries, the delivering causing the modified surface to comprise roughened areas having a separation between them.
   15. An apparatus comprising:
a modified surface configured to contact an object, the modified surface being formed from a material comprising a grain structure including crystalline grains and grain boundaries, wherein the modified surface has a roughness based at least on a plurality of crystalline grain peaks and a plurality of crystalline grain boundary valleys located below the crystalline grain peaks.
   16. The apparatus of clause 15, wherein the roughness is the root-mean-square of height of the modified surface.
   17. The apparatus of clause 16, wherein the roughness is between 3 and 35 nm.
   18. The apparatus of clause 16, wherein the roughness is between 20 and 35 nm.
   19. The apparatus of clause 16, wherein the roughness of the modified surface is greater than 2 nm.
   20. The apparatus of clause 16, wherein the roughness of the native surface is less than 3 nm.
   21. The apparatus of clause 15, wherein, in at least one location on the modified surface, between 2 nm and 30 nm of grain boundary material was removed from the native surface.
   22. The apparatus of clause 15, further comprising a plurality of burls extending from a substrate, wherein the modified surface is on top surfaces of the plurality of burls.
   23. The apparatus of clause 22, wherein the substrate is a reticle clamp, wafer clamp, or wafer table.
   24. The apparatus of clause 22, further comprising a coating on the top surfaces of the burls and the modified surface is formed in the coating.
   25. The apparatus of clause 24, wherein the coating is a TiN, CrN, or DLC coating.
   26. The apparatus of clause 22, wherein the plurality of burls include a plurality of hills and the modified surface is on the plurality of hills.
   27. The apparatus of clause 26, wherein the modified surface includes a plurality of roughened areas formed across the hills.
   28. The apparatus of clause 15, wherein the modified surface includes roughened areas having a separation between them.
   29. The apparatus of clause 28, wherein the separation between roughened areas is approximately 10 microns.
   30. The apparatus of clause 28, wherein the separation between roughened areas is approximately 15 microns.
   31. The apparatus of clause 28, wherein the separation between roughened areas is approximately 20 microns.
   32. The apparatus of clause 28, wherein the modified surface has an arithmetical mean height (Sa) of between 0.4 nm and 19 nm.
   33. The apparatus of clause 15, wherein the modified surface includes roughened areas where approximately 5 nm of material in at least one of the grain boundaries has been removed.

The concepts disclosed herein may simulate or mathematically model any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The descriptions above are intended to be illustrative, not limiting. Thus, it will be apparent to one skilled in the art that modifications may be made as described without departing from the scope of the claims set out below.

1. A method comprising:
delivering light to a native surface;
ablating at least a portion of the native surface with the delivered light to increase roughness of the native surface; and
forming a modified surface based on the ablating, such that the increased roughness reduces an ability of an object to stick to the modified surface.

2. The method of claim 1, wherein the light is a laser.

3. The method of claim 1, wherein the native surface comprises a top surface of a burl.

4. The method of claim 1, further comprising:
controlling a light source for the delivering, wherein the controlling comprises setting an energy density of the light source to generate light having a fluence at the native surface that, when delivered to the surface, causes the ablation to be selective ablation of the native surface based on an atomic structure of the native surface, the selective ablation reducing a surface area for contacting the object.

5. The method of claim 4, wherein:
the native surface comprising crystalline grains separated by grain boundaries, and
the selective ablation removes material of the grain boundaries and causes essentially no ablation of the crystalline grains.

6. The method of claim 4, the controlling further comprising:
adjusting one or more of an intensity and/or focus of the light source to set the energy density based on a desired roughness of the modified surface.

7. The method of claim 5, the controlling further comprising:
delivering light at separated locations on the native surface causing ablation of a portion of the grain boundaries, the delivering causing the modified surface to comprise roughened areas having a separation between them.

8. The method of claim 7, wherein the separation is greater than a spot size of the light source.

9. The method of claim 1, wherein a separation between locations of the delivery of the light is less than a spot size of the light.

10. The method of claim 1, wherein the delivering of the light is across a plurality of hilltops on a top surface of a burl forming part of a reticle clamp.

11. A non-transitory machine-readable medium storing instructions which, when executed by at least one programmable processor, cause the at least one programmable processor to perform operations comprising:
delivering light to a native surface;
ablating at least a portion of the native surface with the delivered light to increase roughness of the native surface; and
forming a modified surface based on the ablating, such that the increased roughness reduces an ability of an object to stick to the modified surface.

12. The non-transitory machine-readable medium of claim 11, the operations further comprising:
controlling a light source for the delivering, wherein the controlling comprises setting an energy density of the light source to generate light having a fluence at the native surface that, when delivered to the surface, causes the ablation to be selective ablation of the native surface based on an atomic structure of the native surface, the selective ablation reducing a surface area for contacting the object.

13. The non-transitory machine-readable medium of claim 12, the controlling further comprising:
adjusting one or more of an intensity and/or focus of the light source to set the energy density based on a desired roughness of the modified surface.

14. The non-transitory machine-readable medium of claim 12, the controlling further comprising:
delivering light at separated locations on the native surface causing ablation of a portion of the grain boundaries, the delivering causing the modified surface to comprise roughened areas having a separation between them.

15. An apparatus comprising:
a modified surface configured to contact an object, the modified surface being formed from a material comprising a grain structure including crystalline grains and grain boundaries,
wherein the modified surface has a roughness based at least on a plurality of crystalline grain peaks and a plurality of crystalline grain boundary valleys located below the crystalline grain peaks.
